(19) United States
(12) Patent Application Publication
(10) Pub. No.: US 2017/0062679 A1
(43) Pub. Date: Mar. 2, 2017

(54) DISPLAY APPARATUS INCLUDING SURFACE PLASMON LAYER

(71) Applicant: Samsung Display Co., Ltd., Yongin-si (KR)

(72) Inventors: Hyesog Lee, Yongin-si (KR); Yunseon Do, Yongin-si (KR); Jaejoong Kwon, Yongin-si (KR)

(21) Appl. No.: 15/138,355

(22) Filed: Apr. 26, 2016

(30) Foreign Application Priority Data
Aug. 31, 2015 (KR) 10-2015-0123196

(51) Int. Cl. H01L 33/60; H01L 27/15; H01L 33/58; H01L 33/06; H01L 33/36

(52) U.S. Cl. CPC H01L 33/60; H01L 33/06; H01L 33/36; H01L 33/58; H01L 27/15

(57) ABSTRACT

A display includes a substrate; a first electrode on the substrate; a light-emitting diode (“LED”) on the first electrode; a second electrode on the LED; and a metal layer which is on the first electrode and of which portions thereof at a periphery of the LED define an opening of the metal layer. The first electrode at a region in which the LED is disposed is exposed by the opening of the metal layer.

This application claims priority to Korean Patent Application No. 10-2015-0123196, filed on Aug. 31, 2015, and all the benefits accruing therefrom under 35 U.S.C. §119, the contents of which in their entirety are herein incorporated by reference.

### BACKGROUND

1. Field

One or more exemplary embodiments relate a display apparatus, and more particularly, to a display apparatus that utilizes a light-emitting diode (“LED”).

2. Description of the Related Art

A light-emitting diode (“LED”) is a device that converts an electric signal to light such as infrared rays, visible light, etc. by using characteristics of a compound semiconductor. The LED is used for home appliances in home applications, a remote controller, an electronic board, various kinds of automation apparatuses, etc. The LED is utilized in a wide range of fields of an electronic device from a miniaturized hand-held electronic device to a relatively large-scale display device, and a use range of the LED is gradually extending.

### SUMMARY

For a display apparatus that utilizes a light-emitting diode (“LED”), there is a problem in deterioration of display quality since the light-emitting diode (“LED”) has a relatively small light-emitting area. One or more exemplary embodiments of the present invention include a structure that expands an effective light-emitting area of a display apparatus that utilizes a light-emitting diode (“LED”) having a relatively small initial light-emitting area.

According to one or more exemplary embodiments, a display apparatus includes a substrate; a first electrode on the substrate; a light-emitting diode (“LED”) on the first electrode; a second electrode on the LED; and a metal layer which is on the first electrode and of which portions thereof at a periphery of the LED define an opening of the metal layer. The first electrode at a region in which the LED is disposed is exposed by the opening of the metal layer.

The metal layer may have a rough surface.

The metal layer may include metal having a negative dielectric constant.

The metal layer may have a thickness between about 10 nanometers (nm) and about 50 nm.

The metal layer may include a metal nanostructure.

The display apparatus may further include: an insulating layer between the first electrode and the metal layer.

The insulating layer may define an opening thereof which overlaps the opening of the metal layer.

According to one or more exemplary embodiments, a display apparatus includes a substrate; a first electrode on the substrate; a second electrode on the first electrode; a metal layer on the second electrode; and a light-emitting diode (“LED”) between the first electrode and the second electrode and between the first electrode and the metal layer.

The metal layer may have a rough surface.

The metal layer may include metal having a negative dielectric constant.

The metal layer may have a thickness between about 10 nm and about 50 nm.

The metal layer may include a metal nanostructure.

According to one or more exemplary embodiments, a display apparatus include a substrate; a first electrode on the substrate; a second electrode on the first electrode; a light-emitting diode which generates light and is between the first electrode and the second electrode, where the generated light travels in a light emission path defined from the light-emitting diode; and a metal layer disposed in the light emission path defined from the light-emitting diode.

The metal layer may be disposed between the first electrode and the second electrode.

The display apparatus may further include: an insulating layer between the first electrode and the metal layer.

The LED may be disposed between the first electrode and the second electrode and between the first electrode and the metal layer.

The metal layer may be a thin film metal layer and may define a rough surface thereof.

The metal layer may include metal having a negative dielectric constant.

The metal layer may have a thickness between about 10 nm and about 50 nm.

The metal layer may be a metal nanostructure.

### BRIEF DESCRIPTION OF THE DRAWINGS

These and/or other advantages will become apparent and more readily appreciated from the following description of the exemplary embodiments, taken in conjunction with the accompanying drawings in which:

FIG. 1 is a schematic plan view of an exemplary embodiment of a display apparatus according to the invention;

FIG. 2 is a schematic plan view of an exemplary embodiment of a pixel of the display apparatus of FIG. 1;

FIG. 3 is a cross-sectional view taken along line X-X′ of FIG. 2;

FIG. 4 is an enlarged cross-sectional view of an exemplary embodiment of a portion of a metal layer in a pixel of a display apparatus according to the invention;

FIG. 5 is a diagram for describing light extraction by a metal layer in a pixel of a display apparatus according to the invention;

FIG. 6 is a cross-sectional view of another exemplary embodiment of a pixel of the display apparatus of FIG. 1, taken along line X-X′ of FIG. 2, according to the invention; and

FIG. 7 is a cross-sectional view of still another exemplary embodiment of a pixel of the display apparatus of FIG. 1, taken along line X-X′ of FIG. 2, according to the invention.

### DETAILED DESCRIPTION

As the invention allows for various changes and numerous embodiments, exemplary embodiments will be illustrated in the drawings and described in detail in the written description. Effects and characteristics of present exemplary embodiments, and a method of accomplishing them will be apparent by referring to content described below in detail together with the drawings. However, the invention is not limited to the exemplary embodiments described below and may be implemented in various forms.

Hereinafter, the invention will be described more fully with reference to the accompanying drawings, in which exemplary embodiments of the invention are shown. When description is made with reference to the drawings, like reference numerals in the drawings denote like or corresponding elements, and repeated description thereof will be omitted.

It will be understood that although the terms “first,” “second,” etc. may be used herein to describe various components, these components should not be limited by these terms. These components are only used to distinguish one component from another.

The terminology used herein is for the purpose of describing particular embodiments only and is not intended to be limiting. As used herein, the singular forms “a,” “an” and “the” are intended to include the plural forms as well, including “at least one,” unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or component is referred to as being “formed on,” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are arbitrarily illustrated for convenience of explanation, the following embodiments are not limited thereto. As used herein, the term “and/or” includes any and all combinations of one or more of the associated listed items. Expressions such as “at least one of” when preceding a list of elements, modify the entire list of elements and do not modify the individual elements of the list.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

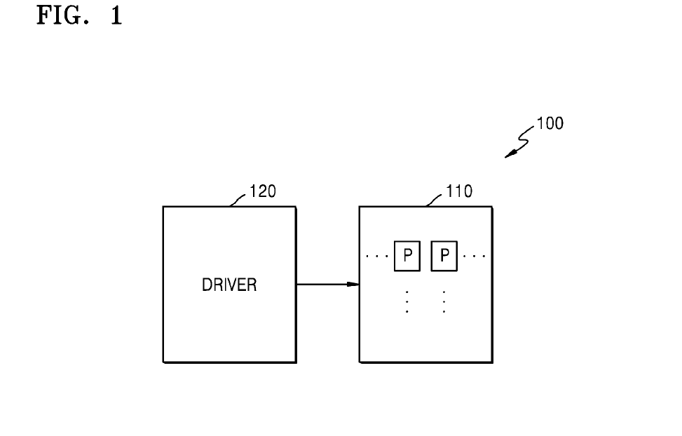

FIG. 1 is a schematic plan view of an exemplary embodiment of a display apparatus 100 according to the invention.

Referring to FIG. 1, the display apparatus 100 may include a display unit 110 which displays an image and a driver 120 which provides a signal to the display unit 110 to drive the display unit 110. The display unit 110 may include a pixel P provided in plural arranged in a matrix on a substrate, and a plural of signal lines disposed on the substrate and connected to the pixels P, within the display unit 110. The driver 120 may include a scan driver that applies a scan signal to a scan line connected to the pixels P and/or a data driver that applies a data signal to a data line connected to the pixels P. The substrate of the display apparatus 100 may be common to both the display unit 110 and the driver 120. The plurality of pixels P may be disposed on a display portion of the substrate at which the image is displayed, while the driver 120 may be disposed on a non-display portion of the substrate at which the image is not displayed.

The driver 120 disposed in the non-display portion of the substrate is disposed at a periphery of the display unit 110 on which the pixels P are arranged. The driver 120 may include an integrated circuit chip and may be directly mounted on the substrate on which the display unit 110 is also disposed or formed, may be mounted on a flexible printed circuit film, may be attached to the substrate in a tape carrier package (“TCP”), or may be directly disposed or formed on the substrate.

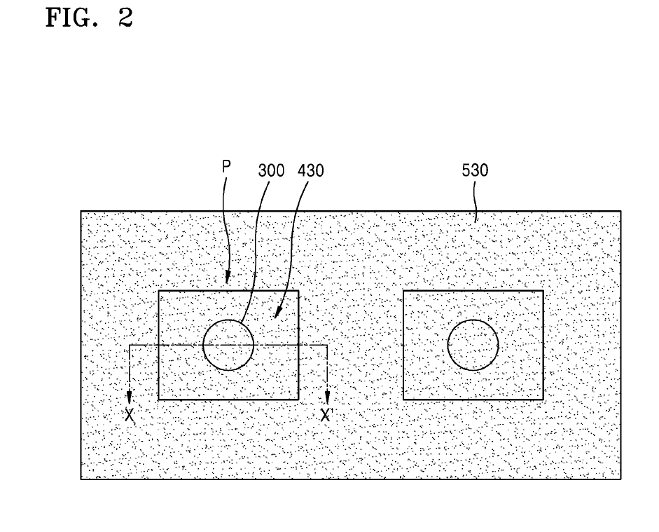

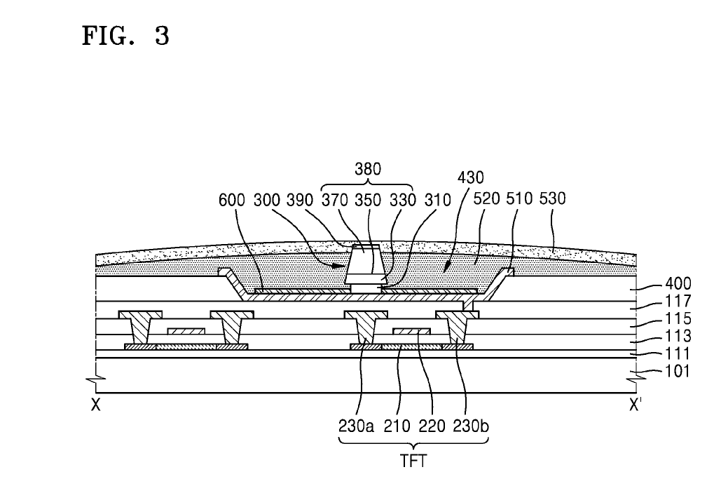

FIG. 2 is a schematic plan view of an exemplary embodiment of the pixel P of the display apparatus 100 of FIG. 1. FIG. 3 is a cross-sectional view taken along line X-X′ of FIG. 2.

Referring to FIGS. 2 and 3, each of the pixels P may include a light-emitting diode (“LED”) 300 and a pixel circuit which is connected to the LED 300. The pixel circuit may include at least one transistor TFT and at least one capacitor. The pixel circuit may be connected to a scan line and a data line that cross each other in the display portion of the substrate. An example of two transistors TFT and the LED 300 connected to one of the two transistors TFT is illustrated in FIG. 3, but the invention is not limited thereto.

A buffer layer 111 may be provided on a substrate 101. The transistor TFTs and the LED 300 may be provided on the buffer layer 111.

The substrate 101 may include glass or plastic, etc. The buffer layer 111 may reduce or effectively prevent penetration of impurity elements via the substrate 101 and planarize the surface of the substrate 101. The buffer layer 111 may include a single layer structure or a multi-layer structure, and may include an inorganic material such as SiNx and/or SiOx.

The transistor TFT may include an active layer 210, a gate electrode 220, a source electrode 230a and a drain electrode 230b. The active layer 210 may include a semiconductor material, and may define a source region thereof, a drain region thereof and a channel region thereof between the source region and the drain region. The gate electrode 220 may be disposed or formed on the active layer 210 and correspond to the channel region of the active layer 210. The source electrode 230a and the drain electrode 230b may be physically and/or electrically connected to the source region and the drain region of the active layer 210, respectively.

A first insulating layer 113 including an inorganic insulating material may define a gate insulating layer between the active layer 210 and the gate electrode 220. A second insulating layer 115 may define an interlayer insulating layer between the gate electrode 220 and the source electrode 230a and between the gate electrode 220 and the drain electrode 230b. A third insulating layer 117 may define a planarization layer on the source electrode 230a and the drain electrode 230b. The second insulating layer 115 and the third insulating layer 117 may include an organic insulating material or an inorganic insulating material, or alternately may include both an organic insulating layer and an inorganic insulating layer.

FIG. 3 illustrates an example of a top gate type transistor TFT in which the gate electrode is disposed on (e.g., above or on top of) the active layer. However, the invention is not limited thereto, and the gate electrode may be disposed below the active layer to define a bottom gate type transistor TFT.

A bank 400 defining a pixel region of the pixel P may be disposed on the third insulating layer 117. The bank 400 may define a concave portion 430 where the LED 300 is accommodated. The height of the bank 400 may be determined by the height of the LED 300 and a viewing angle of the display apparatus 100. The height of the bank 400 may be taken from the substrate 101 or from another underlying layer such as the third insulating layer 117. A size (width) of the concave portion 430 may be determined by the resolution of the display apparatus 100, a pixel density, etc. In an exemplary embodiment, the height of the LED 300 may be greater than the height of the bank 400 taken from the third insulating layer 117. The minimum height of the LED 300 defined by a total height of the elements of the LED 300 may be greater than a maximum height of the bank 400 taken from the third insulating layer 117, such that a portion of the LED 300 extends above an upper surface of the bank 400.

FIG. 2 illustrates an example in which the concave portion 430 has a rectangular planar shape in a top plan view. However, the invention is not limited thereto, and the concave portion 430 may have various planar shapes in the top plan view, such as a polygonal shape, a relatively long rectangular shape, a circular shape, a conical shape, an oval shape, a triangle shape, etc.

A first electrode 510 may be disposed along a lateral (side) surface and a lower surface of the concave portion 430, and the first electrode 510 at the lateral side surface of the concave portion 430 may extend to be disposed on the upper surface of the bank 400 at the periphery of the concave portion 430. The first electrode 510 may be electrically physically and/or electrically connected to the source electrode 230a or the drain electrode 230b of the transistor TFT, through a via hole defined or formed in the third insulating layer 117. In FIG. 3, the first electrode 510 may be electrically connected to the drain electrode 230b at the via hole defined in the third insulating layer 117.

The bank 400 may function as a light-blocking member within the pixel P. The bank 400 may have a relatively low light transmittance and may block light discharged to the lateral side of the LED 300 or the lateral side of the concave portion 430, thereby reducing or effectively preventing a mixture of light from adjacent LEDs 300. The bank 400 may absorb and/or block light incident from outside the pixel P, thereby improving a contrast ratio of the display apparatus 100 such as when the display apparatus 100 is used in a relatively bright environment.

The bank 400 may include a material that absorbs a portion of light incident thereto, a light-reflecting material and/or a light-scattering material. The bank 400 may include a semi-transparent or opaque (non-transparent) insulating material with respect to visible light rays (for example, light in a wavelength ranging from about 380 nanometers (nm) to about 750 nm).

The bank 400 may include a thermo-plastic resin such as polycarbonate (“PC”), polyethylene terephthalate (“PET”), polyether sulfone (“PES”), polyvinyl butyral (“PVB”), polyphenylene ether (“PPE”), polyamide, polyetherimide (“PEI”), a norbornene-based resin, a methacrylic resin, a cyclic polyolefin-based resin, etc., a thermosetting resin such as an epoxy resin, a phenolic resin, a urethane resin, an acrylic resin, a vinyl ester resin, an imide-based resin, a urethane-based resin, a urea resin, a melamine resin, etc., or an organic insulating material such as polystyrene, polyacrylonitrile, polycarbonate, etc., but is not limited thereto.

The bank 400 may include an inorganic insulating material including an inorganic oxide and an inorganic nitride such as SiOx, SiNx, SiNxOy, AlOx, TiOx, TaOx, ZnOx, etc., but is not limited thereto.

In an exemplary embodiment, the bank 400 may include an opaque material such as a black matrix material. Examples of an insulating black matrix material may include resin or paste including glass paste and a black pigment, metal particles such as nickel, aluminum, molybdenum, and an alloy thereof, metal oxide particles (for example, chrome oxide), or metal nitride particles (for example, chrome nitride), etc.

In another exemplary embodiment, the bank 400 may be a distributed-Brag reflector (“DBR”) having high reflectivity or a mirror reflector including metal.

The LED 300 may be disposed in the concave portion 430 of the bank 400. The LED 300 may be a micro LED. In this regard, micro may indicate a size of about 1 micrometer (μm) to about 100 micrometers (μm). However, exemplary embodiments are not limited thereto, and the LED 300 may include an LED that has a size that is larger or smaller than about 1 μm to about 100 μm. The LED 300 may discharge light of a predetermined wavelength that belongs to a wavelength range from ultraviolet rays to visible rays. In an exemplary embodiment, for example, the LED 300 may be a red, green, blue, white or ultraviolet (“UV”) LED which generates red, green, blue, white or ultraviolet (“UV”) light, respectively.

In an exemplary embodiment of manufacturing the display apparatus 100, the LED 300 and the concave portion 430 on the substrate 101 may be provided in plural. The LEDs 300 may be individually or collectively disposed on a wafer and transferred to the substrate 101 of the display apparatus 100, so that the LEDs 300 may be respectively accommodated in the concave portions 430 of the substrate 101.

The LED 300 may include a p-n diode 380, a first contact electrode 310 and a second contact electrode 390. The first contact electrode 310 and/or the second contact electrode 390 may include one or more layers, and may include various conductive materials including metal, conductive oxide and conductive polymers. The first contact electrode 310 and the second contact electrode 390 may selectively include a reflective layer, for example, a silver layer. The first contact electrode 310 may be physically and/or electrically connected to the first electrode 510. The second contact electrode 390 may be electrically connected to a second electrode 530. The p-n diode 380 may include a lower (p−) doped layer 330, an intermediate layer defined by one or more quantum well layers 350, and an upper (n−) doped layer 370. In another exemplary embodiment, the upper doped layer 370 may be a p-doped layer, and the lower doped layer 330 may be an n-doped layer. The p-n diode 380 may define a rectilinear (e.g., non-tapered) lateral wall thereof or an upward or downward tapered lateral wall thereof.

The first electrode 510 may include or define a reflective electrode and include one or more layers. In an exemplary embodiment, for example, the first electrode 510 may include one or more layers of a metal material such as aluminum, molybdenum, titanium, an alloy of titanium and tungsten, silver or gold, or an alloy thereof. The first electrode 510 may include a transparent conductive layer including a conductive material such as a transparent conductive oxide (“TCO”) including indium tin oxide (“ITO”), indium zinc oxide (“IZO”), ZnO, or In₂O₃, etc., a carbon nanotube film, or a transparent conductive polymer, and a reflective layer in addition to the transparent conductive layer, such as to define a double layer structure thereof. In an exemplary embodiment, the first electrode 510 may have a triple layer structure including upper and lower transparent conductive layers and a reflective layer which is between the upper and lower transparent conductive layers.

The second electrode 530 may include or define a transparent or semitransparent electrode. In an exemplary embodiment, for example, the second electrode 530 may include a conductive material such as a TCO including ITO, IZO, ZnO, or In₂O₃, etc., a carbon nanotube film, or a transparent conductive polymer. The second electrode 530 may be disposed or formed on the entire substrate 101 such as to define a common electrode of the pixels P.

A passivation layer 520 may surround the LED 300 which is disposed in the concave portion 430. The passivation layer 520 may cover the bank 400 and the LED 300. The passivation layer 520 may be disposed or formed not to cover an upper portion of the LED 300, e.g. the second contact electrode 390 of the LED 300, and thus the second contact electrode 390 may be exposed from the passivation layer 520. The passivation layer 520 may include an organic insulating layer. In an exemplary embodiment, for example, the passivation layer 520 may include acryl, polymethyl methacrylate (“PMMA”), benzocyclobutene (“BCB”), polyimide, acrylate, epoxy, polyester, etc., but is not limited thereto. The second electrode 530 is physically and/or electrically connected to the exposed second contact electrode 390 of the LED 300 and may be disposed or formed on the passivation layer 520.

A metal layer 600 disposed or formed at the periphery of the LED 300 may be disposed on the first electrode 510. In FIG. 3, the metal layer 600 may be directly in contact with the first contact electrode 310 of the LED 300 but is not limited thereto. In an alternative exemplary embodiment, the metal layer 600 may be spaced apart from (e.g., not in direct contact with) the first contact electrode 310 of the LED 300. The metal layer 600 may be disposed on a path of light downward discharged from the LED 300. In an exemplary embodiment, for example, the metal layer 600 may be disposed at an upper portion of the first electrode 510 which is located on a bottom surface of the concave portion 430. The metal layer 600 may define an opening thereof in a region at which the LED 300 is disposed or is to be transferred in a method of manufacturing the display apparatus 100. A portion of the first electrode 510 may be exposed by the opening of the metal layer 600. In an exemplary embodiment of manufacturing the display apparatus 100, the LED 300 may be transferred into the opening of the metal layer 600 so that the LED 300 is disposed in contact with the first electrode 510.

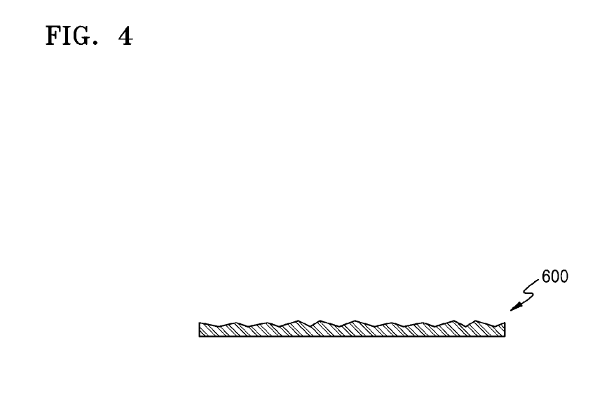

In an exemplary embodiment, as shown in FIG. 4, the metal layer 600 may be a metal thin film having a relatively rough surface. The metal layer 600 may include metal having a negative (−) dielectric constant within a visible wavelength range and having an intrinsic surface plasmon frequency identical or close to a frequency of light discharged by the LED 300. In an exemplary embodiment, for example, the metal layer 600 may include metal that relatively easily induces surface plasmon such as gold (Au), silver (Ag), platinum (Pt), palladium (Pd), copper (Cu), silicon (Si), germanium (Ge), aluminum (Al), or a combination thereof. The metal layer 600 may have a cross-sectional thickness ranging from about 10 nm and about 50 nm. In an exemplary embodiment, a maximum cross-sectional thickness defined by the metal layer 600 may be between about 10 nm and about 50 nm. As the rough surface, the metal layer 600 may define a surface thereof having no periodicity in an uneven structure such that light may exit through a surface plasmon process of coupling the light discharged by the LED 300 to the surface plasmon generated on a metal surface of the metal layer 600.

In an exemplary embodiment of manufacturing the display apparatus 100 including the metal layer 600, the metal layer 600 may be formed using various methods. In an exemplary embodiment, the metal layer 600 may be formed on the first electrode 510 by forming a photoresist pattern that exposes a region of the first electrode 510 on which a metal material is to be disposed, on the substrate 101, depositing the metal material on the exposed region of the first electrode 510 and removing the photoresist pattern, before transferring the LED 300 onto the substrate 101. In another exemplary embodiment, the metal layer 600 may be formed by depositing a metal material onto the first electrode 510 on the substrate 1091 and etching the deposited metal material using photolithography, before transferring the LED 300 onto the substrate 101. The metal material may be deposited using physical vapor deposition such as sputtering, electron beam deposition, etc. so that the finally formed metal layer 600 may have a relatively rough surface.

In another exemplary embodiment, the metal layer 600 may be a metal nanostructure (nonoparticle, nanorod, nanohole, etc.) having a size ranging from several nm to several hundreds of nm such as metal or metal oxide, etc. A shape of the metal nanostructure is not limited but may be a shape such as a globular shape, an oval globular shape, etc.

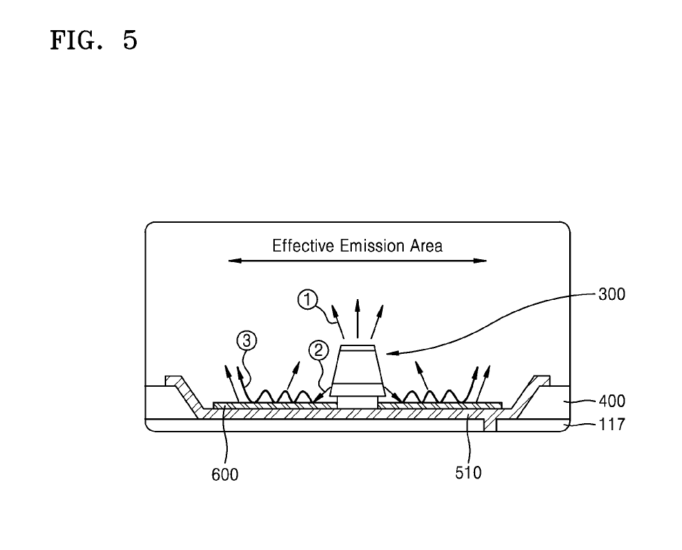

FIG. 5 is a diagram for describing light extraction by a metal layer in a pixel of a display apparatus according to the invention.

Surface plasmon is a collective vibration of surface electrons generated when light resonates free electrons present on a metal surface and the free electrons travel along the metal surface. In the exemplary embodiment of the invention, the metal surface on which free electrodes are present is formed as an uneven structure so that the surface plasmon that travels along the metal surface is discharged from metal of member defining the metal surface thereof as light.

Among lights generated by the LED 300, a second portion of light \textcircled{2} discharged from a bottom portion of the LED 300 at a lower portion thereof, other than a first portion of light \textcircled{1} discharged from a front surface of the LED 300 at an upper portion thereof, may be incident to the metal layer 600. The second portion of light \textcircled{2} is generally transmitted toward the metal layer 600 while the first portion of light \textcircled{1} is generally transmitted away from the metal layer 600. Within the pixel, the second portion of light \textcircled{1} incident to the metal layer 600 may be coupled to the surface plasmon, may travel along an uneven structure of a surface of the metal layer 600 by several and several tens of microns, and may be scattered by the uneven structure of the surface of the metal layer 600. Thus, the second portion of the light \textcircled{2} may be finally discharged from the pixel toward a front surface of the pixel as light \textcircled{3}. The scattered light \textcircled{3} may be discharged at a different location from an incidence location of the light \textcircled{2}, e.g., a location disposed away from the LED 300.

That is, in the exemplary embodiment of the invention, due to the first portion of light \textcircled{1} discharged from the front surface of the LED 300 and the light \textcircled{3} discharged from the pixel by traveling along the metal surface though a surface plasmon process, light extraction efficiency and a light-emitting region of the pixel and of the display apparatus may be increased, thereby increasing light-emitting efficiency and light-emitting intensity thereof.

If the uneven structure of the metal layer is formed as a grating structure having periodicity (e.g., uniform pitch or height of unevenness), the surface plasmon has a relatively narrow band wavelength (e.g., a specific wavelength). The relatively narrow band wavelength of the surface plasmon resonance increases the light extraction efficiency of light having the same frequency as the surface plasmon. However, processing complexity and cost used to form a delicate uneven structure such as the above-described grating structure is increased.

In one or more exemplary embodiment, the metal layer 600 having an uneven surface, where the uneven surface is defined by a non-uniform pitch or a height of the metal layer 600 such as due to a deposition process of metal, may be formed. The uneven surface which defines a rough surface of the metal layer 600 may result in the surface plasmon having a relatively broad wavelength band. That is, in one or more exemplary embodiment, the metal layer 600 may be provided, thereby simply extracting a broadband of light from a visible ray band to an ultraviolet ray band generated by the LED 300 and/or a near-infrared ray band generated by the LED, at relatively low cost. The light-emitting diode (“LED”) may have a relatively small initial light-emitting area, such as defined by a structure of the light-emitting diode (“LED”). Since the metal layer 600 extracts a broadband of light from the light generated by the light-emitting diode (“LED”), an effective light-emitting area of the light-emitting diode (“LED”) and a display apparatus that utilizes the light-emitting diode (“LED”) is advantageously expanded.

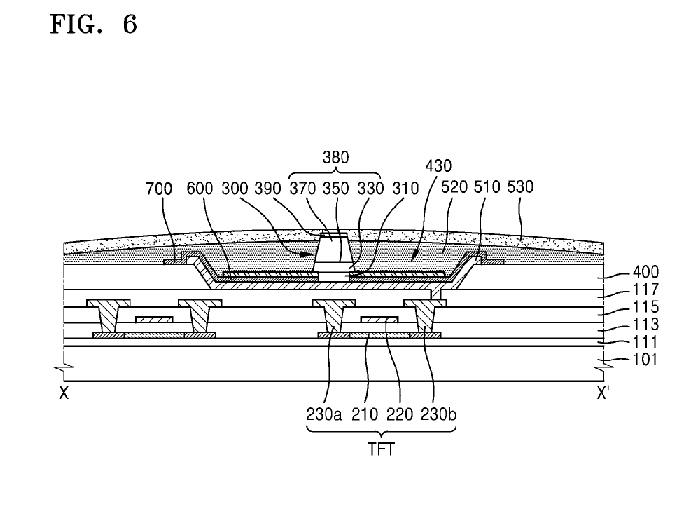

FIG. 6 is a cross-sectional view of another exemplary embodiment of a pixel of the display apparatus of FIG. 1, taken along line X-X′ of FIG. 2, according to the invention.

The embodiment of FIG. 6 is different from the embodiment of FIG. 3 in that an insulating layer 700 is further disposed between the first electrode 510 and the metal layer 600. Redundant descriptions between FIGS. 2 through 6 are omitted below.

Referring to FIG. 6, the buffer layer 111 may be provided on the substrate 101, and the transistor TFT and the LED 300 may be provided on the buffer layer 111. The substrate 101 may include glass or plastic, etc.

The transistor TFT may include the active layer 210, the gate electrode 220, the source electrode 230a and the drain electrode 230b. The active layer 210 may include a semiconductor material, and may define a source region thereof, a drain region thereof, and a channel region thereof between the source region and the drain region. The gate electrode 220 may be disposed or formed on the active layer 210 and correspond to the channel region of the active layer 210. The source electrode 230a and the drain electrode 230b may be physically and/or electrically connected to the source region and the drain region of the active layer 210, respectively. The first insulating layer 113 may define a gate insulating layer between the active layer 210 and the gate electrode 220. The second insulating layer 115 may define an interlayer insulating layer between the gate electrode 220 and the source electrode 230a and between the gate electrode 220 and the drain electrode 230b. The third insulating layer 117 may define a planarization layer on the source electrode 230a and the drain electrode 230b. The layer 700 may define a fourth insulating layer in the pixel P.

The bank 400 defining a pixel region of the pixel P may be disposed on the third insulating layer 117. The bank 400 may define the concave portion 430 where the LED 300 is accommodated. The height of the bank 400 may be determined by the height of the LED 300 and a viewing angle of the display apparatus 100. A size (width) of the concave portion 430 may be determined by the resolution of the display apparatus 100, a pixel density, etc. In an exemplary embodiment, the height of the LED 300 may be greater than the height of the bank 400.

The first electrode 510 may be disposed along the lateral (side) surface and the lower surface of the concave portion 430, and the first electrode 510 at the lateral side surface of the concave portion 430 may extend to be disposed on the upper surface of the bank 400 at the periphery of the concave portion 430. The first electrode 510 may be physically and/or electrically connected to the source electrode 230a or the drain electrode 230b of the transistor TFT through a via hole formed in the third insulating layer 117.

The bank 400 may include a material that absorbs a portion of a light, a light-reflecting material or a light-scattering material, and may function as a pixel P light-blocking member having a relatively low light transmittance.

The LED 300 may be disposed in the concave portion 430 of the bank 400. The LED 300 may be a micro LED. The LED 300 may discharge light of a predetermined wavelength that belongs to a wavelength range from ultraviolet rays to visible rays. In an exemplary embodiment, for example, the LED 300 may be a red, green, blue, white or ultraviolet (UV) LED.

The LED 300 may include the p-n diode 380, the first contact electrode 310 and the second contact electrode 390. The first contact electrode 310 may be physically and/or electrically connected to the first electrode 510. The second contact electrode 390 may be physically and/or electrically connected to the second electrode 530. The p-n diode 380 may include the lower (p−) doped layer 330, the intermediate layer defined by the one or more quantum well layers 350, and the upper (n−) doped layer 370. In another exemplary embodiment, the upper doped layer 370 may be the p-doped layer, and the lower doped layer 330 may be the n-doped layer.

The first electrode 510 may include or define a reflective electrode and may include one or more layers. The second electrode 530 may include or define a transparent or semitransparent electrode.

The passivation layer 520 may surround the LED 300 which is disposed in the concave portion 430. The passivation layer 520 may cover the bank 400 and the LED 300. The passivation layer 520 may be disposed or formed not to cover an upper portion of the LED 300, e.g. the second contact electrode 390, and thus the second contact electrode 390 may be exposed from the passivation layer 520. The passivation layer 520 may include an organic insulating layer. The second electrode 530 electrically connected to the exposed second contact electrode 390 of the LED 300 may be disposed or formed on the passivation layer 520.

The metal layer 600 disposed or formed at the periphery of the LED 300 may be disposed on the first electrode 510. The metal layer 600 may define an opening thereof at a region to which the LED 300 is to be transferred or is disposed. A portion of the first electrode 510 may be exposed by the opening of the metal layer 600.

In an exemplary embodiment, the metal layer 600 may be a metal thin film having a relatively rough surface. The metal layer 600 may include metal having a negative (−) dielectric constant within a visible wavelength range and having an intrinsic surface plasmon frequency identical or close to a frequency of light discharged by the LED 300. The metal layer 600 may have a cross-sectional thickness ranging from about 10 nm to about 50 nm. In another exemplary embodiment, the metal layer 600 may be a metal nanostructure such as metal or metal oxide, etc.

The insulating layer 700 may be disposed between the first electrode 510 and the metal layer 600 in the cross-sectional thickness direction of the pixel P. The insulating layer 700 may have a function of insulating the first electrode 510 and the metal layer 600 from each other. The insulating layer 700 may be disposed at an upper portion of the first electrode 510 and at a lower portion of the metal layer 600 and essentially function as a dielectric substance. The metal layer 600 may be disposed only in one region of the insulating layer 700 and may guide light incident thereto.

The insulating layer 700 disposed between the first electrode 510 and the metal layer 600 may cover the first electrode 510 and may be formed along the lateral (side) surface and the lower surface of the concave portion 430. The insulating layer 700 at the lateral side surface of the concave portion 420 may be extended to be disposed on the upper surface of the bank 400 at the periphery of the concave portion 430. The insulating layer 700 may define an opening corresponding to or overlapping with the opening in the metal layer 600. A portion of the first electrode 510 may be exposed by the overlapping openings of the metal layer 600 and the insulating layer 700. The LED 300 may be disposed in or transferred into the openings of the insulating layer 700 and the metal layer 600, and may be in contact with the exposed portion of the first electrode 510. The insulating layer 700 may have a cross-sectional thickness more than several hundreds of nm.

The insulating layer 700 may include a dielectric material. In an exemplary embodiment, for example, the dielectric material may include at least one of oxide such as silicon oxide (SiO₂), titanium oxide (TiO₂), tantalum oxide (Ta₂O₅), or aluminum oxide (Al₂O₃), and PMMA but is not limited thereto.

In an exemplary embodiment of manufacturing the display apparatus 100, the insulating layer 700 may be formed simultaneously with the metal layer 600. In an exemplary embodiment, the insulating layer 700 may be formed simultaneously with the metal layer 600 by forming a photoresist pattern on the substrate 101 that exposes a region of the first electrode 510 on which a metal material from which is formed the metal layer 600 and a dielectric material from which is formed the insulating layer 700 are to be disposed, sequentially depositing the dielectric material and the metal material, and removing the photoresist pattern before transferring the LED 300 on the substrate 101. In another exemplary embodiment, the insulating layer 700 may be formed simultaneously with the metal layer 600 by sequentially depositing the dielectric material and the metal material onto the first electrode 510 and etching the deposited dielectric material and metal material using photolithography before transferring the LED 300 on the substrate 101. The dielectric material and the metal material may be deposited using physical vapor deposition such as sputtering, electron beam deposition, etc. Alternatively, the dielectric material and the metal material may be deposited by coating and curing coating a liquid including the dielectric material.

Different from the metal layer 600, the insulating layer 700 may not be a totally planar member. The insulating layer 700 may define a curved profile as being extended along the lateral side surface of the concave portion 430. In an exemplary embodiment, the metal layer 600 may also have a curved profile due to a surface shape of the underlying curved profile insulating layer 700.

A distance of surface plasmon that travels along a rough surface of the metal layer 600 may be increased by adjusting a refractive index and thickness of the insulating layer 700. Increasing the distance of the surface plasmon increases light extraction efficiency and a light-emitting region of the pixel and of the display apparatus, thereby increasing light-emitting efficiency and light-emitting intensity thereof.

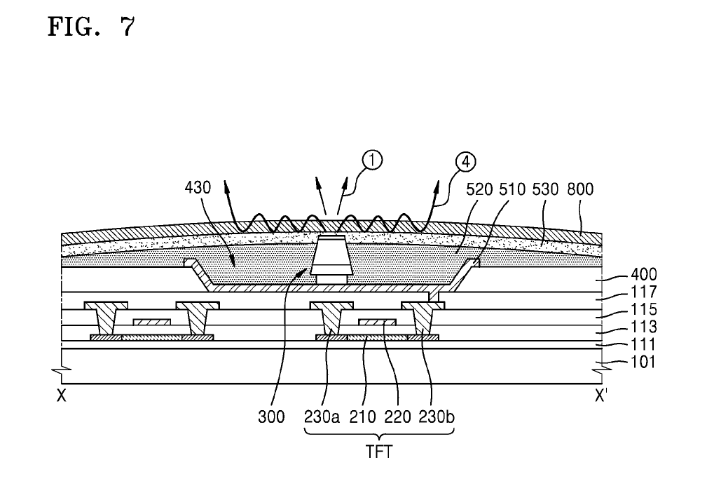

FIG. 7 is a cross-sectional view of still another exemplary embodiment of a pixel of a display apparatus of FIG. 1, taken along line X-X′ of FIG. 2, according to the invention.

In the embodiment of FIG. 7, a metal layer 800 may be further provided on the second electrode 530. Redundant descriptions between FIGS. 2 through 6 are omitted below.

Referring to FIG. 7, the buffer layer 111 may be provided on the substrate 101, and the transistor TFT and the LED 300 may be provided on the buffer layer 111. The substrate 101 may include glass or plastic, etc.

The transistor TFT may include the active layer 210, the gate electrode 220, the source electrode 230a and the drain electrode 230b. The active layer 210 may include a semiconductor material, and define a source region thereof, a drain region thereof, and a channel region thereof between the source region and the drain region. The gate electrode 220 may be disposed or formed on the active layer 210 and correspond to the channel region of the active layer 210. The source electrode 230a and the drain electrode 230b may be physically and/or electrically connected to the source region and the drain region of the active layer 210, respectively. The first insulating layer 113 may define a gate insulating layer between the active layer 210 and the gate electrode 220. The second insulating layer 115 may define an interlayer insulating layer between the gate electrode 220 and the source electrode 230a and between the gate electrode 220 and the drain electrode 230b. The third insulating layer 117 may define a planarization layer on the source electrode 230a/drain electrode 230b.

The bank 400 defining a pixel region of the pixel P may be disposed on the third insulating layer 117. The bank 400 may define the concave portion 430 where the LED 300 is accommodated. The height of the bank 400 may be determined by the height of the LED 300 and a viewing angle of the display apparatus 100. A size (width) of the concave portion 430 may be determined by the resolution of the display apparatus 100, a pixel density, etc. In an exemplary embodiment, the height of the LED 300 may be greater than the height of the bank 400.

The first electrode 510 may be disposed along the lateral (side) surface and the lower surface of the concave portion 430, and the first electrode 510 at the lateral side surface of the concave portion 430 may extend to be disposed on the upper surface of the bank 400 at the periphery of the concave portion 430. The first electrode 510 may be physically and/or electrically connected to the source electrode 230a or the drain electrode 230b of the transistor TFT through a via hole formed in the third insulating layer 117.

The bank 400 may include a material that absorbs a portion of a light, a light-reflecting material or a light-scattering material and may function as a pixel P light-blocking member having a relatively low light transmittance.

The LED 300 may be disposed in the concave portion 430 of the bank 400. The LED 300 may be a micro LED. The LED 300 may discharge light of a predetermined wavelength that belongs to a wavelength range from ultraviolet rays to visible rays. In an exemplary embodiment, for example, the LED 300 may be a red, green, blue, white or ultraviolet (UV) LED.

The LED 300 may include the p-n diode 380, the first electrode 310 and the second contact electrode 390. The first contact electrode 310 may be physically and/or electrically connected to the first electrode 510. The second contact electrode 390 may be physically and/or electrically connected to the second electrode 530. The p-n diode 380 may include the lower (p−) doped layer 330, the intermediate layer defined by the one or more quantum well layers 350, and the upper (n−) doped layer 370. In another exemplary embodiment, the upper doped layer 370 may be the p-doped layer, and the lower doped layer 330 may be the n-doped layer.

The first electrode 510 may include or define a reflective electrode and include one or more layers. The second electrode 530 may include or define a transparent or semitransparent electrode.

The passivation layer 520 may surround the LED 300 which is disposed in the concave portion 430. The passivation layer 520 may cover the bank 400 and the LED 300. The passivation layer 520 may be disposed or formed not to cover an upper portion of the LED 300, e.g. the second contact electrode 390, and thus the second contact electrode 390 may be exposed from the passivation layer 520. The passivation layer 520 may include an organic insulating layer. The second electrode 530 electrically connected to the exposed second contact electrode 390 of the LED 300 may be disposed or formed on the passivation layer 520.

The metal layer 800 may be disposed or formed on the second electrode 530. The metal layer 800 may be disposed to cover the second electrode 530 on a path of light upward discharged from the LED 300, e.g., on the second electrode 530. In an exemplary embodiment, the metal layer 800 may be a metal thin film having a relatively rough surface. The metal layer 800 may include metal having a negative (−) dielectric constant within a visible wavelength range and having an intrinsic surface plasmon frequency identical or close to a frequency of light discharged by the LED 300. The metal layer 800 may have a cross-sectional thickness ranging from about 10 nm and about 50 nm. In another exemplary embodiment, the metal layer 800 may be a metal nanostructure such as metal or metal oxide, etc.

Referring to FIG. 7, light discharged from a front surface of the LED 300 may transmit through the transparent second electrode 530 and then may be incident to the transparent metal layer 800. Among lights discharged from the front surface of the LED 300, a first portion of the light may transmit through the metal layer 800 in an initial transmission direction and then may be discharged from the metal layer 800 in substantially the initial transmission direction (refer to \textcircled{1} in FIG. 7), and a second portion of the light may travel along a surface of the metal layer 800 in a direction different from the initial transmission direction, through a surface plasmon process on the metal layer 800 and then may be discharged from the metal layer 800 (refer to \textcircled{4} in FIG. 7).

That is, in the present embodiment, due to the light \textcircled{1} discharged from the pixel P by being emitted from the front surface of the LED 300 and the light \textcircled{4} discharged from the pixel P by traveling along the surface of the metal layer 800 though the surface plasmon process, light extraction efficiency and a light-emitting region of the pixel and of the display apparatus may be increased, thereby increasing light-emitting efficiency and light-emitting intensity thereof.

A vertical micro LED is illustrated as an example of the LED 300 in the above-described exemplary embodiments but the invention is not limited thereto. A flip micro LED in which a first contact electrode and a second contact electrode are disposed in the same direction, a horizontal micro LED, etc. may be used as the LED 300. In this case, locations of a first electrode and a second electrode may correspond to locations of the first contact electrode and the second contact electrode.

Although light extraction from a visible ray range to an infrared ray range and/or a near infrared ray range is described in the above-described embodiments, surface plasmon may be induced by using a material (for example, metal, a high density doped semiconductor material, etc.) suitable for the light extraction of a different frequency range (band) (for example, infrared ray) instead of the metal layers 600 and 800.

A display apparatus according to one or more exemplary embodiment may include a metal layer that induces the surface plasmon on a light path for each pixel among a plurality of pixels, thereby increasing a light-emitting area of each pixel. Therefore, a non-display region perceived on the display apparatus that uses a LED may be reduced.

As described above, according to an exemplary embodiment, a metal layer is provided on a path of light downward discharged by an LED and/or a path of light upward discharged by the LED, thereby expanding a light-emitting area of a display apparatus that utilizes the LED.

Though the invention has been described with reference to exemplary embodiments illustrated in the drawings, these are provided for an exemplary purpose only, and those of ordinary skill in the art will understand that various modifications and other equivalent embodiments may be made therein. Therefore, the spirit and scope of the invention should be defined by the following claims.

What is claimed is:

1. A display apparatus comprising:
a substrate;
a first electrode on the substrate;
a light-emitting diode on the first electrode;
a second electrode on the light-emitting diode; and
a metal layer which is on the first electrode and of which portions thereof at a periphery of the light-emitting diode define an opening of the metal layer,
wherein the first electrode in a region in which the light-emitting diode is disposed is exposed by the opening of the metal layer.

2. The display apparatus of claim 1, wherein the metal layer has a rough surface.

3. The display apparatus of claim 2, wherein the metal layer comprises a metal having a negative dielectric constant.

4. The display apparatus of claim 2, wherein the metal layer has a thickness between about 10 nanometers and about 50 nanometers.

5. The display apparatus of claim 1, wherein the metal layer comprises a metal nanostructure.

6. The display apparatus of claim 5, further comprising:
an insulating layer between the first electrode and the metal layer.

7. The display apparatus of claim 6, wherein the insulating layer defines an opening thereof which overlaps the opening of the metal layer.

8. A display apparatus comprising:
a substrate;
a first electrode on the substrate;
a second electrode on the first electrode;
a metal layer on the second electrode; and
a light-emitting diode between the first electrode and the second electrode and between the first electrode and the metal layer,
wherein the metal layer has a rough surface.

9. The display apparatus of claim 8, wherein the metal layer comprises a metal having a negative dielectric constant.

10. The display apparatus of claim 8, wherein the metal layer has a thickness between about 10 nanometers and about 50 nanometers.

11. The display apparatus of claim 8, wherein the metal layer comprises a metal nanostructure.

12. A display apparatus comprising:
a substrate;
a first electrode on the substrate;
a second electrode on the first electrode;
a light-emitting diode which generates light and is between the first electrode and the second electrode, wherein the generated light travels in a light emission path defined from the light-emitting diode; and
a metal layer disposed in the light emission path defined from the light-emitting diode.

13. The display apparatus of claim 12, wherein the metal layer is disposed between the first electrode and the second electrode.

14. The display apparatus of claim 13, further comprising:
an insulating layer between the first electrode and the metal layer.

15. The display apparatus of claim 12, wherein the light-emitting diode is disposed between the first electrode and the second electrode and between the first electrode and the metal layer.

16. The display apparatus of claim 12, wherein the metal layer is a thin film metal layer and defines a rough surface thereof.

17. The display apparatus of claim 12, wherein the metal layer comprises a metal having a negative dielectric constant.

18. The display apparatus of claim 12, wherein the metal layer has a thickness between about 10 nanometers and about 50 nanometers.

19. The display apparatus of claim 12, wherein the metal layer is a metal nanostructure.
